(19) United States
(12) Patent Application Publication
(10) Pub. No.: US 2026/0034681 A1
(43) Pub. Date: Feb. 5, 2026

(54) SUBSTRATE TRANSFER ROBOT SYSTEM, SEMICONDUCTOR TRANSFER APPARATUS, SEMICONDUCTOR MANUFACTURING APPARATUS, AND CONTROL METHOD THEREOF

(71) Applicant: KABUSHIKI KAISHA YASKAWA DENKI, Fukuoka (JP)

(72) Inventors: Akihiro SHIOTA, Fukuoka (JP); Daisuke SHIN, Fukuoka (JP); Yoshiki KIMURA, Fukuoka (JP)

(21) Appl. No.: 19/282,829

(22) Filed: Jul. 28, 2025

(30) Foreign Application Priority Data
Jul. 31, 2024 (JP) 2024-124362

(51) Int. Cl. B25J 11/00; B25J 9/04; B25J 9/16; H01L 21/687

(52) U.S. Cl. CPC B25J 11/0095; B25J 9/042; B25J 9/1694; H01L 21/68707

(57) ABSTRACT

A substrate transfer robot system includes: a first arm unit that changes a position of an end with respect to a base in a first plane; a second arm unit that changes a position of the hand with respect to the end in a second plane perpendicular to the first plane; and a control unit that controls the first arm unit and the second arm unit to move the hand while compensating, by the first arm unit, for a displacement of the hand caused by a change in amount of deflection of the first arm unit and the second arm unit.

### CROSS REFERENCES TO RELATED APPLICATIONS

This application is based on and claims priority from Japanese Patent Application No. 2024-124362, filed on Jul. 31, 2024, with the Japan Patent Office, the disclosure of which is incorporated herein in its entirety by reference.

### TECHNICAL FIELD

The present disclosure relates to a substrate transfer robot system, a semiconductor transfer apparatus, a semiconductor manufacturing apparatus, and a control method thereof.

### BACKGROUND

Japanese Patent Laid-Open Publication No. 2018-167380 discloses a transfer robot equipped with a base unit, an arm unit, and a hand unit connected to the arm unit. In the transfer robot, the arm unit includes a vertical arm unit operating vertically and a horizontal arm unit operating horizontally. The vertical arm unit is connected to the base unit, the horizontal arm unit is connected to the vertical arm unit, and the hand unit is connected to the horizontal arm unit.

### SUMMARY

The present disclosure provides a substrate transfer apparatus, which is effective in achieving both a substrate transfer across a wide area and the accuracy of substrate transfer.

According to an aspect of the present disclosure, a substrate transfer robot system includes: a first arm unit that includes a first set of arms connected to each other to individually rotate around a horizontal axis, and that changes a position of an end with respect to a base in a first plane; a second arm unit that includes a second set of arms connected in an order from the end to individually rotate around an axis perpendicular to the horizontal axis, and a hand supporting a substrate in an arm of the second set of arms, which is farthest from the end, and that changes a position of the hand with respect to the end in a second plane perpendicular to the first plane; and a control unit that controls the first arm unit and the second arm unit to move the hand while compensating, by the first arm unit, for a displacement of the hand caused by a change in amount of deflection of the first arm unit and the second arm unit.

According to another aspect of the present disclosure, a semiconductor transfer apparatus includes: a housing that accommodates the substrate transfer robot system; a cassette support that is provided in the housing, and supports a cassette accommodating a substrate; and a pre-aligner that is provided in the housing, and rotates the substrate, wherein the control unit controls the first arm unit and the second arm unit to move the hand into/out of each of a plurality of transfer destinations including the pre-aligner and the cassette, while compensating, by the first arm unit, for the displacement of the hand caused by the change in amount of deflection.

According to yet another aspect of the present disclosure, a semiconductor manufacturing apparatus includes: the semiconductor transfer apparatus; and a processing apparatus that is connected to the semiconductor transfer apparatus, and performs a processing for forming a semiconductor on the substrate.

According to still yet another aspect of the present disclosure, a control method includes: in order to transfer a substrate to a transfer destination, controlling a first arm unit that includes a first set of arms connected to each other to individually rotate around a horizontal axis, and that changes a position of an end with respect to a base in a first plane, and a second arm unit that includes a second set of arms connected in an order from the end to individually rotate around an axis perpendicular to the horizontal axis, and a hand supporting the substrate in an arm of the second set of arms, which is farthest from the end, and that changes a position of the hand with respect to the end in a second plane perpendicular to the first plane; and during a transfer of the substrate, controlling the first arm unit and the second arm unit to move the hand while compensating, by the first arm unit, for a displacement of the substrate caused by a change in amount of deflection of the first arm unit and the second arm unit.

According to the present disclosure, it is possible to provide a substrate transfer apparatus, which is effective in achieving both the substrate transfer across a wide area and the accuracy of substrate transfer.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic view illustrating a semiconductor manufacturing apparatus.

FIG. 2 is a cross-sectional view taken along the line II-II in FIG. 1.

FIG. 3 is a view illustrating a displacement of a hand caused by a change in deflection amount.

FIG. 4 is a schematic view illustrating a motion path.

FIG. 5 is a schematic view illustrating a correction of the motion path.

FIGS. 6A to 6C are schematic views illustrating a correction of entry/exit paths and a relay path.

FIG. 7 is a view illustrating an object sensor.

FIG. 8 is a schematic view illustrating a relationship between a tilt angle of the hand and a result of detection of substrate thickness.

FIG. 9 is a schematic view illustrating a generation of a motion path.

FIGS. 10A to 10C are schematic views illustrating a generation of entry/exit paths and a relay path.

FIG. 11 is a view illustrating a hardware configuration of a controller.

FIG. 12 is a flowchart illustrating a path generation process.

FIG. 13 is a flowchart illustrating a path correction process.

FIG. 14 is a flowchart illustrating a control process.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure will be described in detail with reference to the accompanying drawings. In the descriptions, the same components or components having the same function will be denoted with the same reference numerals, and overlapping descriptions thereof will be omitted.

### <Semiconductor Manufacturing Apparatus>

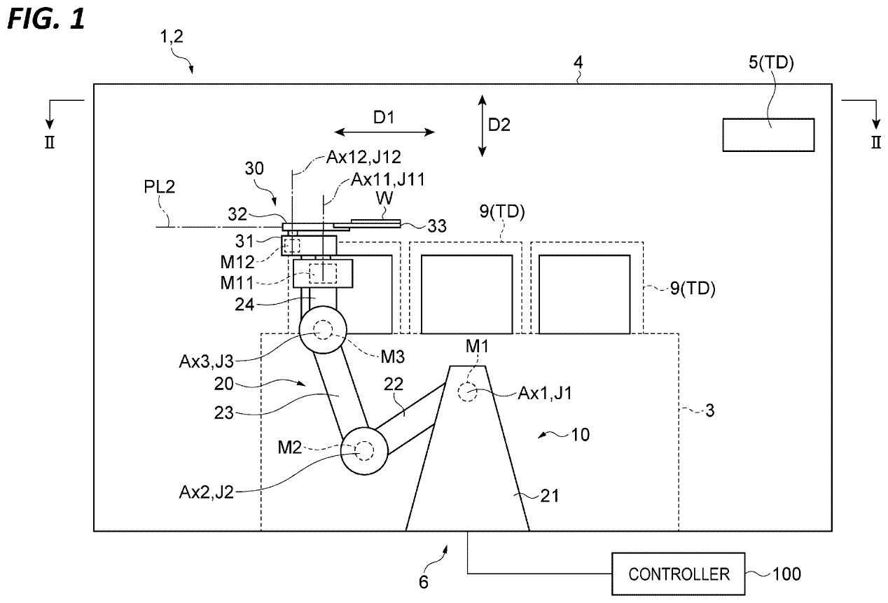

A semiconductor manufacturing apparatus 1 illustrated in FIG. 1 performs at least part of a semiconductor manufacturing process. For example, the semiconductor manufacturing apparatus 1 includes a semiconductor transfer apparatus 2 and a processing apparatus 7. The processing apparatus 7 performs a processing such as a film deposition and etching on a substrate W (e.g., a semiconductor substrate). The semiconductor transfer apparatus 2 takes a substrate W out of a cassette accommodating a plurality of substrates W to transfer the substrate W to the processing apparatus 7, and returns the processed substrate W from the processing apparatus 7 to the cassette.

The semiconductor transfer apparatus 2 includes a cassette support 3, a housing 4, a pre-aligner 5, and a substrate transfer robot system 6. The cassette support 3 supports a plurality of cassettes 9 arranged in the horizontal arrangement direction D1. Each of the plurality of cassettes 9 accommodates a plurality of substrates W. The housing 4 is disposed between the plurality of cassettes 9 supported by the cassette support 3 and the processing apparatus 7, to accommodate the substrate W transferred between the plurality of cassettes 9 and the processing apparatus 7. The pre-aligner 5 is a device that rotates the substrate W to align the orientation of the substrate W (e.g., the crystal orientation) with a predetermined direction. For example, the pre-aligner 5 is accommodated in the housing 4. The substrate transfer robot system 6 transfers the substrate W to a transfer destination TD (e.g., the plurality of cassettes 9, the pre-aligner 5, and a plurality of chambers of the processing apparatus 7) in the housing 4. Hereinafter, the configuration of the substrate transfer robot system 6 will be described.

### <Robot System>

The substrate transfer robot system 6 includes a robot 10 and a controller 100. The housing 4 accommodates at least the robot 10. The robot 10 includes a first arm unit 20 and a second arm unit 30. The first arm unit 20 includes a base 21, arms 22 and 23, an end 24, and motors M1, M2, and M3, and changes the position of the end 24 with respect to the base 21 within a first plane PL1 by the arms 22 and 23. For example, the first plane PL1 extends along the vertical direction D2 (up-down direction) and the arrangement direction D1.

A first set of arms 22 and 23 is connected to each other such that each rotates around a horizontal axis. The “horizontal axis” refers to an axis along the horizontal plane. For example, the arm 22 is connected to the base 21 to rotate around a horizontal axis Ax1, and extends away from the horizontal axis Ax1. The arm 23 is connected to the arm 22 to rotate around a horizontal axis Ax2, and extends away from the horizontal axis Ax2. The end 24 is connected to the arm 23 to rotate around a horizontal axis Ax3. As an example, the horizontal axes Ax1, Ax2, and Ax3 are parallel to each other, and each perpendicular to the first plane PL1.

According to the configuration above, the first arm unit 20 includes an end joint J3 that rotates the end 24 around the horizontal axis Ax3, and one or more (e.g., two) arm joints J1 and J2 that change the position of the end joint J3 with respect to the base 21 in the first plane PL1. The motors M1, M2, and M3 drive the arm joints J1 and J2, and the end joint J3, respectively. For example, the motor M1 rotates the arm 22 around the horizontal axis Ax1 at the arm joint J1. The motor M2 rotates the arm 23 around the horizontal axis Ax2 at the arm joint J2. The motor M3 rotates the end 24 around the horizontal axis Ax3 at the end joint J3.

The second arm unit 30 includes a second set of arms 31 and 32, a hand 33, and motors M11 and M12, and changes the position of the hand 33 with respect to the end 24 in a second plane PL2 by the second set of arms 31 and 32. The second plane PL2 refers to a plane perpendicular to the first plane PL1. The second set of arms 31 and 32 is connected in this order from the end 24 such that each rotates around an axis perpendicular to the horizontal axis. For example, the arm 31 is connected to the end 24 to rotate around an axis Ax11, and extends away from the axis Ax11. The arm 32 is connected to the arm 31 to rotate around an axis Ax12, and extends away from the axis Ax12. The axes Ax11 and Ax12 are parallel to each other.

The hand 33 supports the substrate W at the arm 32. For example, the hand 33 is fixed to the arm 32, and is wide along the plane perpendicular to the horizontal axis Ax3. The hand 33 supports the substrate W from below in a posture perpendicular to the horizontal axis Ax3.

According to the configuration described above, the second arm unit 30 includes joints J11 and J12 that change the position of the hand 33 with respect to the end 24 in the second plane PL2. The motors M11 and M12 drive the joints J11 and J12, respectively. For example, the motor M11 rotates the arm 31 around the axis Ax11 at the joint J11. The motor M12 rotates the arm 32 around the axis Ax12 at the joint J12.

The configuration described above is merely an example, and may be modified. For example, each of the first arm unit 20 and the second arm unit 30 only needs to include at least one arm, and may include three or more arms. While descriptions have been made on an example where the second arm unit 30 includes a single set including the arm 32, the hand 33, and the motor M12, the second arm unit 30 may include two or more sets each including the arm 32, the hand 33, and the motor M12. In this case, in each of the two or more sets, the motor M12 rotates the arm 32 around the axis Ax12.

The controller 100 controls the robot 10 to move the hand 33 in the vertical direction and the horizontal direction, while maintaining the hand 33 substantially in the horizontal posture. By operating the first arm unit 20 and the second arm unit 30 in combination, the substrate W may be transferred across a wide area. Meanwhile, when the first arm unit 20 and the second arm unit 30 operate in combination, the displacement of the hand 33 caused by a change in amount of deflection of the first arm unit 20 and the second arm unit 30 increases. The deflection of the first arm unit 20 and the second arm unit 30 occurs at each of the arm joints J1 and J2, the end joint J3, the joints J11 and J12, the first set of arms 22 and 23, and the second set of arms 31 and 32. The deflection amount at each part differs according to a change in bending moment.

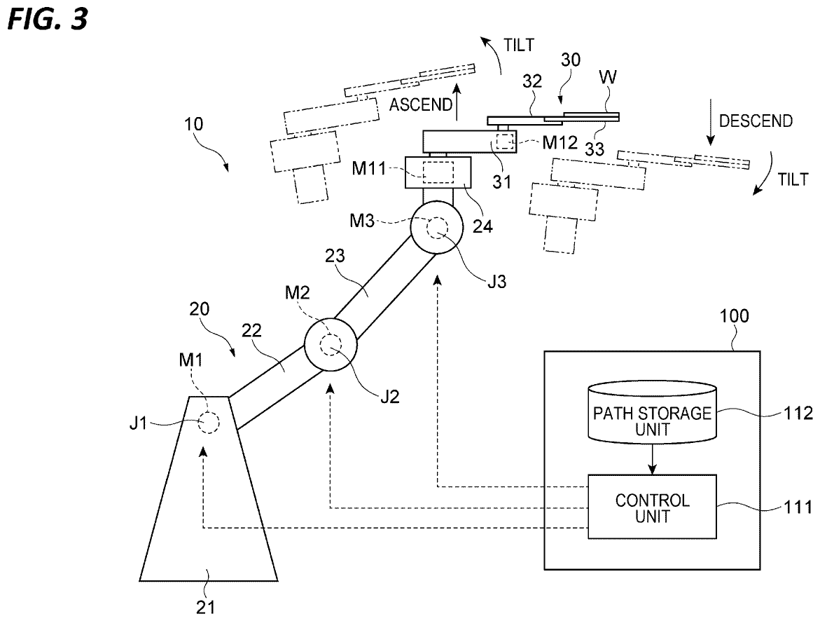

For example, when the hand 33 is displaced in the direction away from the base 21 along the horizontal plane, the bending moment acting on each part increases. Thus, as illustrated in FIG. 3, the deflection amount increases as the hand 33 moves away from the base 21, and the hand 33 tilts forward while slightly descending. Meanwhile, when the hand 33 is displaced in the direction approaching the base 21 along the horizontal plane, the deflection moment acting on each part decreases.

Thus, the controller 100 controls the first arm unit 20 and the second arm unit 30 to move the hand 33 while compensating, by the first arm unit 20, for the displacement of the hand 33 caused by the change in amount of deflection of the first arm unit 20 and the second arm unit 30. The compensation for the displacement indicates decreasing (e.g., substantially offsetting) the displacement. By compensating for the displacement of the hand 33 caused by the change in deflection amount, it is possible to achieve both the transfer of the substrate W across the wide area and the accuracy of transfer of the substrate W.

For example, the controller 100 includes a control unit 111 as a functional component (hereinafter, referred to as a “functional block”). The control unit 111 drives the motors M1, M2, and M3 and the motors M11 and M12 to move the hand 33 in the vertical direction and the horizontal direction, thereby transferring the substrate W to the transfer destination TD, while maintaining the hand 33 substantially in the horizontal posture. As described above, the displacement of the hand 33 caused by the change in deflection amount includes a tilt of the hand 33 and a change in height of the hand 33. The control unit 111 may drive the motor M3 to compensate for the tilt of the hand 33 caused by the change in deflection amount (control the end joint J3), and may drive the motors M1 and M2 to compensate for the change in height of the hand 33 caused by the change in deflection amount (control the arm joints J1 and J2). The change in both tilt and height of the hand 33 caused by the change in deflection amount may easily be compensated for by the first arm unit 20.

For example, the control unit 111 controls the first arm unit 20 to compensate for the change in tilt and height of the hand 33 caused by the change in deflection amount, while moving the hand 33 in the horizontal direction. The accuracy of transfer of the substrate W may be further improved.

The control unit 111 may control the first arm unit 20 to compensate for the displacement of the hand 33 caused by the change in deflection amount, with a specific compensation amount for each transfer destination TD. The compensation amount refers to a compensation amount for substantially eliminating the displacement of the hand 33 caused by the deflection of the first arm unit 20 and the second arm unit 30 at each position during the movement. The “specific compensation amount” for each transfer destination TD does not indicate a single value, but refers to a series of compensation amounts varying with the displacement of the hand 33 along the horizontal direction.

The distance from the base 21 to the hand 33 in the horizontal direction differs according to the transfer destination TD. Thus, the deflection amount of the first arm unit 20 and the second arm unit 30 differs according to the transfer destination TD. The amount of displacement of the hand 33 caused by the change in deflection amount also differs according to the transfer destination TD. Therefore, by compensating for the displacement of the hand 33 caused by the change in deflection amount with the specific compensation amount for each transfer destination TD, the accuracy of transfer of the substrate W may be further improved.

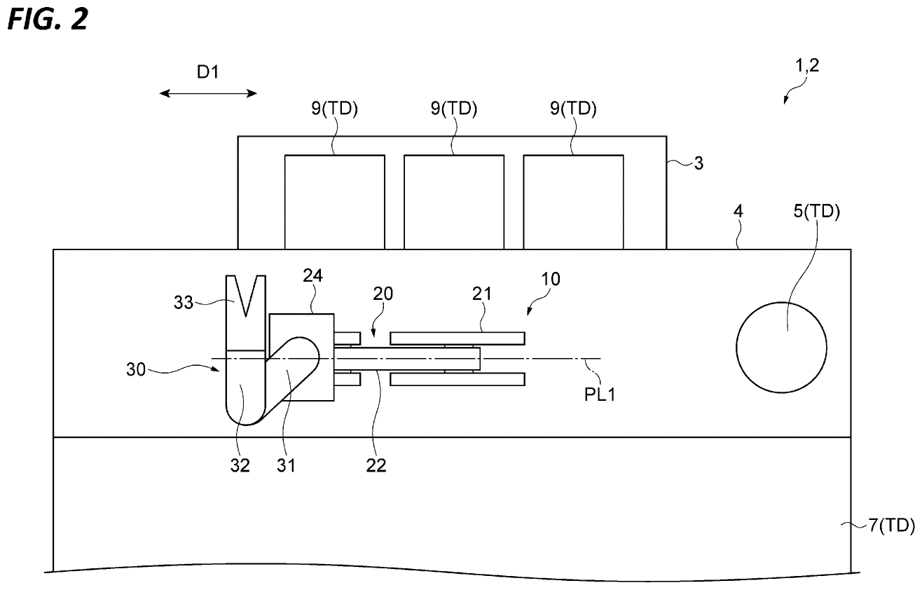

For example, in the layout illustrated in FIGS. 1 and 2, the transfer destination TD farthest from the base 21 is a pre-aligner PA. In this example, the control unit 111 compensates for the displacement of the hand 33 caused by the change in deflection amount, with a maximum compensation amount for the pre-aligner.

The control unit 111 may control the first arm unit 20 and the second arm unit 30 based on a motion path generated in advance to compensate for the displacement of the hand 33 caused by the change in deflection amount by the first arm unit 20. The deflection amount has a reproducibility. Thus, it is possible to generate a motion pattern incorporating the compensation amount for compensating for the displacement of the hand 33 caused by the change in deflection amount. By using the motion pattern incorporating the compensation amount, the displacement of the hand 33 caused by the change in deflection amount may easily be compensated for with a high reproducibility.

For example, the controller 100 further includes a path storage unit 112. The path storage unit 112 stores the motion path generated in advance to compensate for the displacement of the hand 33 caused by the change in deflection amount. The motion path includes a plurality of time-series motion commands. Each of the plurality of motion commands includes a target position that uniquely defines the posture of the robot 10. The target position may include a target position and a target posture of the hand 33, and may include target angles of the arm joints J1 and J2, the end joint J3, and the joints J11 and J12.

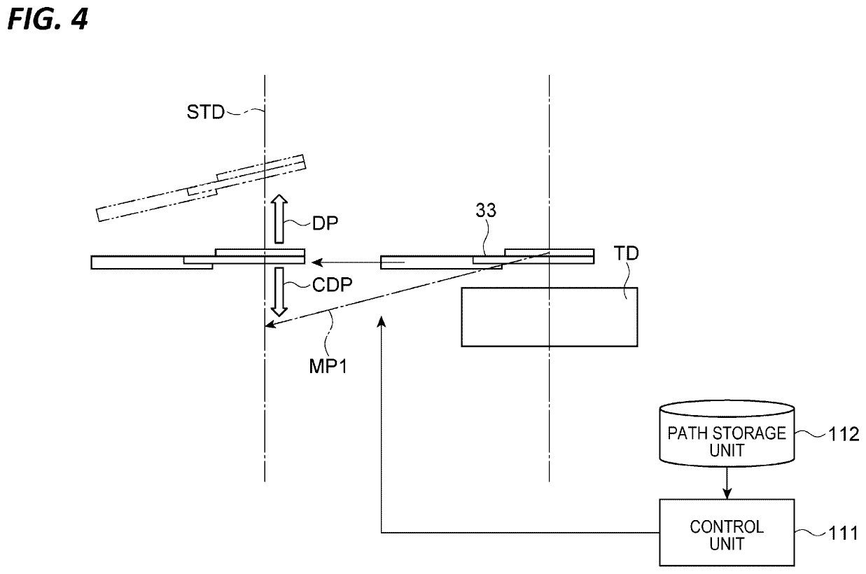

For example, as illustrated in FIG. 4, the motion path includes a path MP1 that changes the tilt and the height of the hand 33 in an opposite direction to the change in tilt and height of the hand 33 caused by the change in deflection amount, while the hand 33 is moving in the horizontal direction. By combining a change DP in tilt and height of the hand 33 caused by the change in deflection amount and a change CDP in tilt and height of the hand 33 caused by the path above, the control unit 111 controls the first arm unit 20 and the second arm unit 30 such that the tilt and the height of the hand 33 are within a specific range with respect to the horizontal line, while the hand 33 is moving in the horizontal direction. For example, the path MP1 is a path that descends the hand 33 to prevent the hand 33 from ascending due to the change in deflection amount, while the hand 33 is moving in the direction approaching the base 21 along the horizontal line. For example, the target position of the hand 33 included in each of the plurality of motion commands of the path MP1 gradually descends as the hand 33 moves in the direction approaching the base 21. Further, the target posture of the hand 33 included in each of the plurality of motion commands of the path MP1 gradually tilts forward as the hand 33 moves in the direction approaching the base 21.

The path MP1 may be a path that moves the hand 33 along the horizontal line between the transfer destination TD of the substrate W and a predetermined position STD away from the transfer destination TD. The description “along the horizontal line” indicates that the tilt and the height of the hand 33 are maintained within a specific range with respect to the horizontal line.

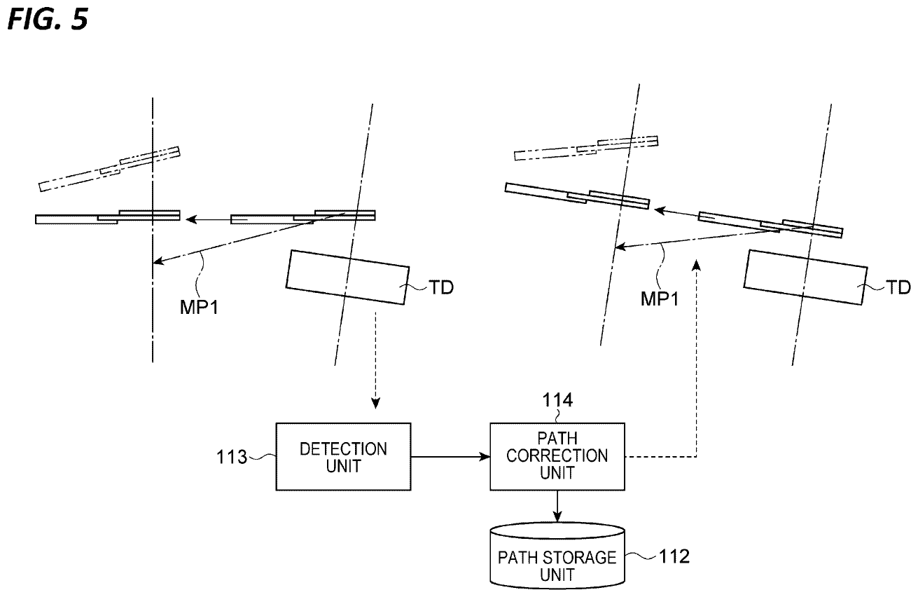

As illustrated in FIG. 5, the controller 100 may further include a detection unit 113 and a path correction unit 114. The detection unit 113 detects the position and the tilt of the transfer destination TD of the substrate W in an actual environment. The path correction unit 114 corrects the motion path based on the result of detection of the position and the tilt of the transfer destination TD. For example, the path correction unit 114 calculates a difference between the position and the tilt of the transfer destination TD and design values, and shifts the path MP1 according to the calculated difference. The position and the tilt of the transfer destination TD are the position and the tilt with respect to the base 21.

The position and the tilt of the transfer destination TD in the actual environment may be slightly different from the design values. Hereinafter, the difference between the position and the tilt of the transfer destination TD in the actual environment and the design values will be referred to as the “positional deviation of the transfer destination TD.” Since the positional deviation of the transfer destination TD is minor, the generated motion path is shifted in accordance with the positional deviation of the transfer destination TD, and therefore, may be used as a motion path to compensate for the displacement of the hand 33 caused by the change in deflection amount in the actual environment. Since it may be unnecessary to re-generate the motion path to compensate for the displacement of the hand 33 caused by the change in deflection amount from the beginning in the actual environment, the motion path may easily be generated for each actual environment.

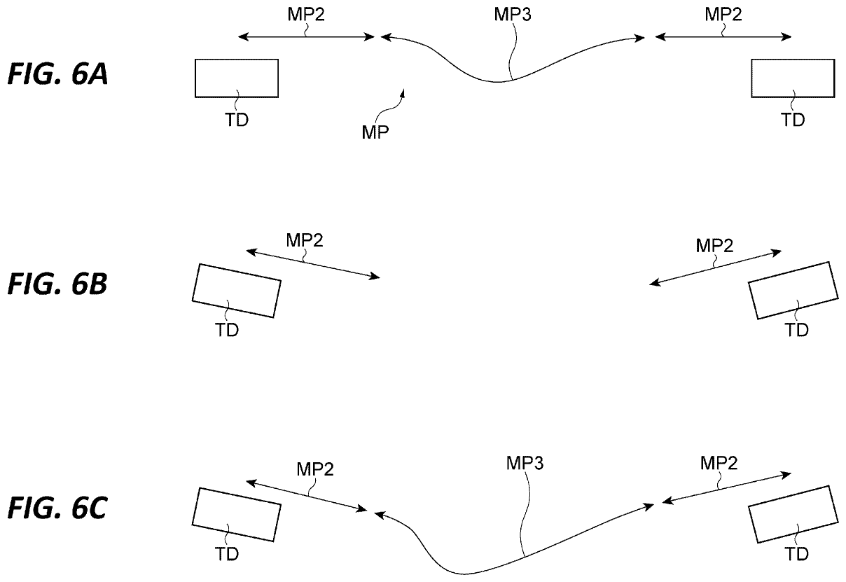

As illustrated in FIG. 6A, the motion path MP may include a plurality of entry/exit paths MP2 and at least one relay path MP3. The plurality of entry/exit paths MP2 are determined for transfer destinations TD, respectively, to move the hand 33 into/out of a corresponding transfer destination TD along the horizontal direction while compensating for the change in tilt and height of the hand 33 caused by the change in deflection amount. The relay path MP3 is determined to connect the plurality of entry/exit paths MP2 to each other.

The detection unit 113 may detect the position and the tilt of each transfer destination TD. As illustrated in FIG. 6B, the path correction unit 114 may correct a corresponding entry/exit path MP2 based on the result of detection of the position and the tilt of each transfer destination TD. As illustrated in FIG. 6C, the path correction unit 114 may correct the relay path MP3 based on the plurality of corrected entry/exit paths MP2, to connect the plurality of corrected entry/exit paths MP2 to each other. The compensation for the displacement of the substrate W caused by the change in deflection amount may easily be applied to the actual environment for each transfer destination TD.

The detection unit 113 may detect the height and the thickness of the substrate W placed in the transfer destination TD, and detect the position and the tilt of the transfer destination TD based on the result of detection of the height and the thickness of the substrate W.

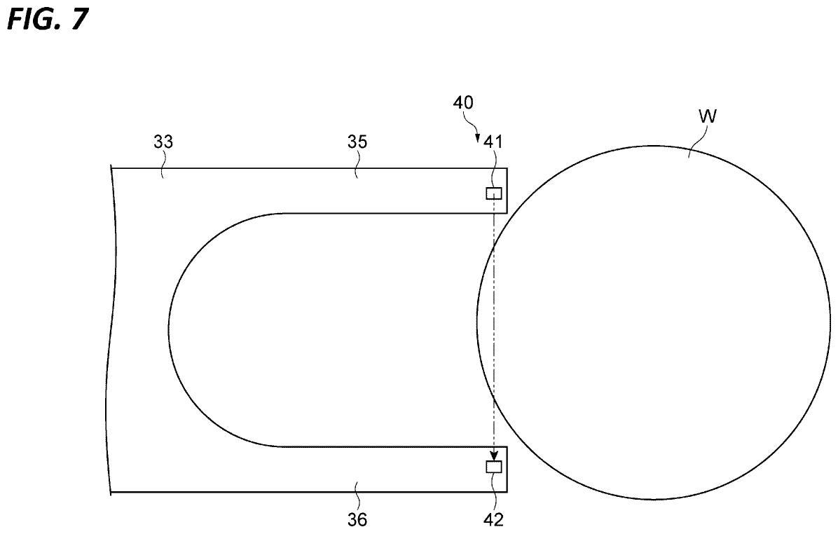

For example, as illustrated in FIG. 7, the substrate transfer robot system 6 may further include an object sensor 40 provided in the hand 33. The object sensor 40 detects whether an object is present at a processing position. Examples of the object sensor 40 include laser, capacitive, and ultrasonic sensors.

For example, the object sensor 40 includes a light emitting device 41 and a light receiving device 42. The light emitting device 41 emits a laser light toward the light receiving device 42. The object sensor 40 detects whether an object is present between the light emitting device 41 and the light receiving device 42, based on whether the light receiving device 42 receives the laser light emitted from the light emitting device 41. For example, the hand 33 includes a pair of fork tips 35 and 36 supporting the substrate W, the light emitting device 41 is provided in the fork tip 35, and the light receiving device 42 is provided in the fork tip 36.

For the detection of the substrate W by the detection unit 113, the control unit 111 moves the hand 33 by the robot 10 to a position where a part of the substrate W enters between the light emitting device 41 and the light receiving device 42 when viewed from above. Then, the control unit 111 moves the hand 33 up or down by the robot 10. The detection unit 113 detects the height and the thickness of the substrate W based on the position of the hand 33 when the object sensor 40 detects the substrate W. For example, the detection unit 113 detects the height and the thickness of the substrate W based on the height of the hand 33 while the object sensor 40 is detecting the substrate W.

The detection unit 113 may repeatedly detect the height and the thickness of the substrate W while changing the tilt of the hand 33, and detect the tilt of the transfer destination TD based on the tilt of the hand 33 when the thickness of the substrate W becomes the smallest. Even when the thickness of the substrate W is unknown, the object sensor 40 provided in the hand 33 may be used for detecting the tilt of the transfer destination TD.

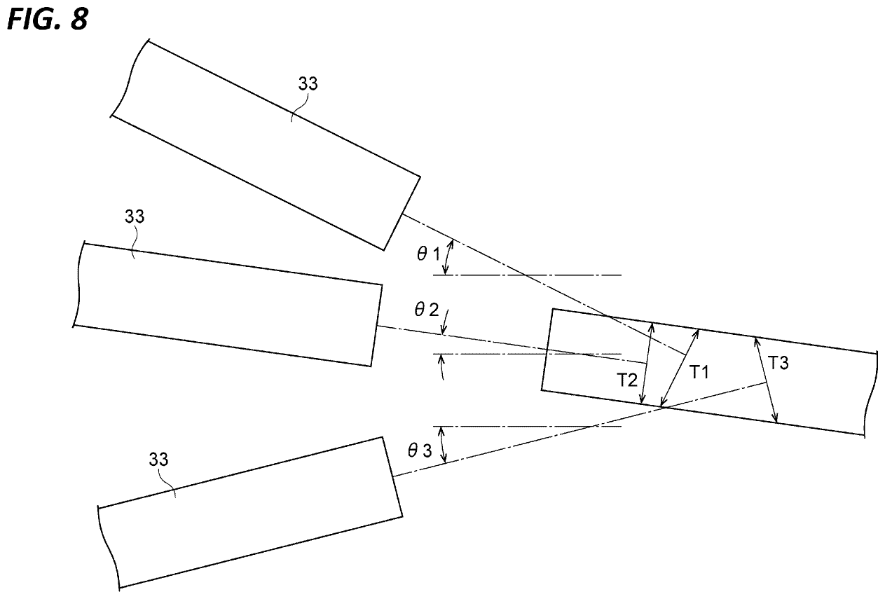

FIG. 8 is a schematic view illustrating the relationship between the tilt angle of the hand 33 and the detected thickness of the substrate W. the thickness T1 is detected at the tilt angle θ1, the thickness T2 is detected at the tilt angle θ2, and the thickness T3 is detected at the tilt angle θ3. Since the tilt of the hand 33 matches the tilt of the substrate W at the tilt angle θ2, the thickness T2 has the smallest value. The detection unit 113 detects the tilt angle θ2 at which the thickness T2 has the smallest value, as the tilt of the substrate W.

Based on the respective rotation angles of the first set of arms 22 and 23, the end 24 and the second set of arms 31 and 32, and the deflection amount when the object sensor 40 detects the substrate W placed in the transfer destination TD, the detection unit 113 may calculate the position of the hand 33 when the object sensor 40 detects the substrate W, and detect the height and the thickness of the substrate W based on the calculated position of the hand 33. For example, the detection unit 113 calculates the position of the hand 33 by the forward kinematics calculation using the rotation angles of the arm joints J1 and J2, the end joint J3, and the joints J11 and J12, and adds the deflection amount to the calculated position, to detect the height and the thickness of the substrate W. The accuracy of detection of the position and the tilt of the transfer destination TD by the object sensor 40 provided in the hand 33 may be improved.

For example, based on the relative rotation angles of the arm joints J1 and J2, the end joint J3, and the joints J11 and J12 when the object sensor 40 actually detects the substrate W with respect to the rotation angles of the arm joints J1 and J2, the end joint J3, and the joints J11 and J12 when the object sensor 40 detects the substrate W placed at a design position, the detection unit 113 may detect the relative position and tilt of the substrate W to the design position. The design position corresponds to the position obtained by adding the deflection amount to the position of the hand 33 calculated by the forward kinematics calculation described above.

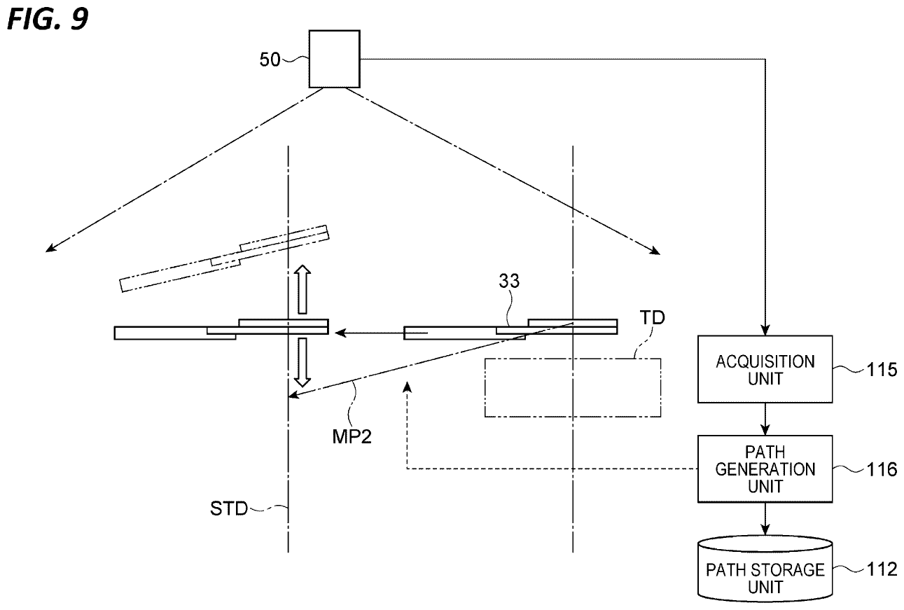

As illustrated in FIG. 9, the controller 100 may further include an acquisition unit 115 and a path generation unit 116. The acquisition unit 115 acquires a result of actual measurement of the displacement of the hand 33 caused by the change in deflection amount. The path generation unit 116 generates a motion path to compensate for the displacement of the hand 33 caused by the change in deflection amount, based on the result of actual measurement.

The acquisition unit 115 detects the displacement of the hand 33 caused by the change in deflection amount, based on the position of the hand 33 detected by, for example, a laser tracker 50. For example, the laser tracker 50 is provided in a plant where the substrate transfer robot system 6 is manufactured, and detects the position of an object in a three-dimensional space by a laser light. For example, the acquisition unit 115 acquires the result of actual measurement of the height and the tilt of the hand 33 and the angles of the arm joints J1 and J2, the end joint J3, and the joints J11 and J12 at each of the position corresponding to the transfer destination TD and the position corresponding to the predetermined position STD described above, and detects the displacement of the hand 33 caused by the change in deflection amount based on the acquired information. The path generation unit 116 corrects the angles of the arm joints J1 and J2, the end joint J3, and the joints J11 and J12 to make the position and the posture of the hand 33 reach the target position and the target posture, at each of the position corresponding to the transfer destination TD and the position corresponding to the predetermined position STD described above. Then, the path generation unit 116 generates the entry/exit path MP2 through a linear interpolation between the corrected position and posture of the hand 33 at the position corresponding to the transfer destination TD and the corrected position and posture of the hand 33 at the position corresponding to the predetermined position STD.

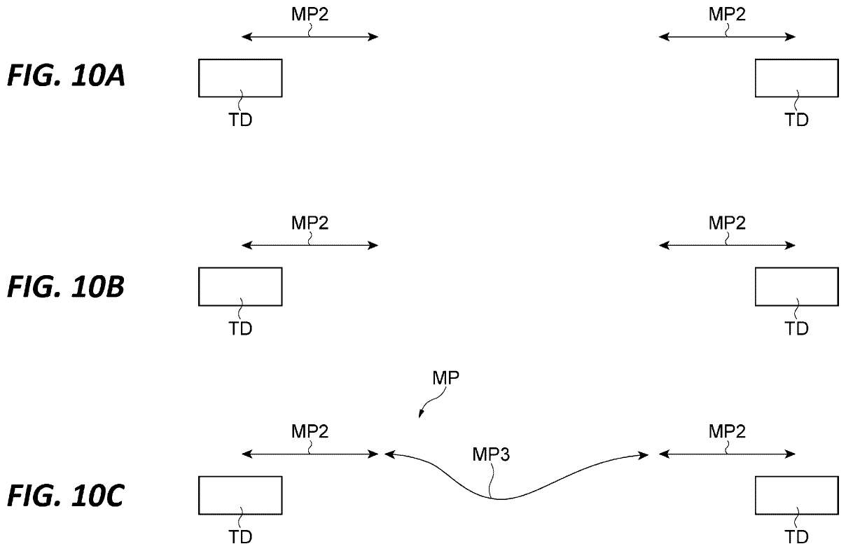

The acquisition unit 115 may acquire the result of actual measurement of the displacement of the hand 33 caused by the change in deflection amount, at each transfer destination TD. As illustrated in FIGS. 10A and 10B, the path generation unit 116 may generate the entry/exit path MP2 for each transfer destination TD based on the result of actual measurement described above, to move the hand 33 into/out of the corresponding transfer destination TD along the horizontal line while compensating for the displacement of the substrate W caused by the change in deflection amount. Then, as illustrated in FIG. 10C, the path generation unit 116 may generate at least one relay path MP3 that connects the plurality of entry/exit paths MP2 to each other. As a result, the motion path MP is generated, including the plurality of entry/exit paths MP2 and at least one relay path MP3. It is possible to easily generate the motion path for compensating for the displacement of the hand 33 caused by the change in deflection amount with the specific compensation amount for each transfer destination TD.

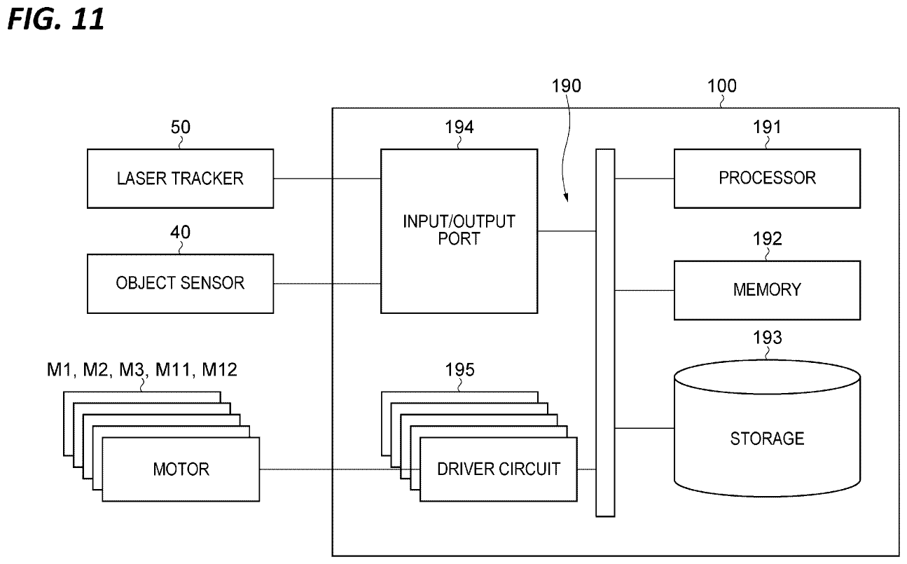

FIG. 11 is a block diagram illustrating a hardware configuration of the controller 100. As illustrated in FIG. 11, the controller 100 includes a circuit 190. The controller 190 includes a processor 191, a memory 192, a storage 193, an input/output port 194, and a driver circuit 195. The storage 193 includes, for example, at least one nonvolatile storage medium. The nonvolatile storage medium includes at least one storage device. Examples of the at least one storage device include a hard disk drive, a solid state drive, and a flash memory. The nonvolatile storage medium may include a portable storage medium such as an optical disk. The storage 193 stores a program for causing the controller 100 to control the robot 10. The program causes the controller 100 to control the first arm unit 20 and the second arm unit 30 to move the hand 33 while compensating, by the first arm unit 20, for the displacement of the hand 33 caused by the change in amount of deflection of the first arm unit 20 and the second arm unit 30. For example, the program causes the controller 100 to configure the controller 100 with the functional blocks described above.

The memory 192 includes at least one volatile storage medium. The volatile storage medium includes at least one memory device. Examples of the at least one memory device include a random access memory (RAM). The memory 192 temporarily stores the program loaded from the storage 193. The processor 191 includes at least one computing device. Examples of the computing device include a central processing unit (CPU) and a graphics processing unit (GPU). The processor 191 executes the program loaded into the memory 192, thereby configuring the controller 100 with the functional blocks described above. The processor 191 may temporarily store calculation results in the memory 192.

The input/output port 194 performs input/output of an electrical signal between the object sensor 40 and the laser tracker 50, according to a request from the processor 191. The driver circuit 195 supplies a drive power to the motors M1, M2, M3, M11, and M12, according to a request from the processor 191.

### <Control Procedure>

A control procedure performed by the controller 100 will be described as an example of a control method. The control procedure includes controlling the first arm unit 20 and the second arm unit 30 to transfer the substrate W to the transfer destination TD, and controlling the first arm unit 20 and the second arm unit 30 to move the hand 33 while compensating, by the first arm unit 20, for the displacement of the hand 33 caused by the change in amount of deflection of the first arm unit 20 and the second arm unit 30, during the transfer of the substrate W.

The control procedure may include a path generation process to generate the motion path described above, a path correction process to correct the motion path, and a control process using the corrected motion path. The path generation process is performed in a plant for manufacturing the substrate transfer robot system 6. The path correction process is performed before the operation of the substrate transfer robot system 6 starts in an actual environment of an installation destination of the substrate transfer robot system 6. The control process is performed during the operation of the substrate transfer robot system 6. Hereinafter, each process will be described.

### (Path Generation Process)

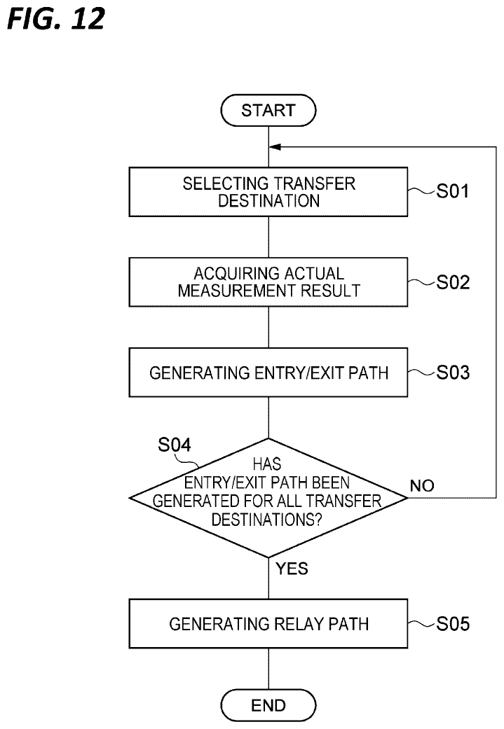

The path generation process is performed in a state where a plurality of entry/exit paths MP2 is temporarily generated by, for example, off-line teaching. Hereinafter, the temporarily generated entry/exit paths MP2 will be referred to as “temporary entry/exit paths MP2.” As illustrated in FIG. 12, the controller 100 first performs steps S01, S02, and S03. In step S01, the control unit 111 selects one of transfer destinations TD. In step S02, the control unit 111 controls the robot 10 to move the hand 33 along the entry/exit path MP2 corresponding to the selected transfer destination TD. The acquisition unit 115 acquires the result of actual measurement of the height and the tilt of the hand 33 and the angles of the arm joints J1 and J2, the end joint J3, and the joints J11 and J12 at each of the position corresponding to the transfer destination TD and the position corresponding to the predetermined position STD described above. In step S03, the path generation unit 116 corrects the temporary entry/exit path MP2 to compensate for the displacement of the hand 33 caused by the change in deflection amount based on the result of actual measurement, thereby generating an entry/exit path MP2.

Next, the controller 100 performs steps S04 and S05. In step S04, the path storage unit 112 checks whether the generation of the entry/exit path MP2 has been completed for all the transfer destinations TD. When it is determined in step S04 that there is still a transfer destination TD for which the entry/exit path MP2 has not been generated, the controller 100 returns the process to step S01. When it is determined in step S04 that the generation of the entry/exit path MP2 has been completed for all the transfer destinations TD, the controller 100 performs step S05. In step S05, the path generation unit 116 generates at least one relay path MP3 that connects the plurality of entry/exit paths MP2 to each other. Then, the path generation process is completed.

### (Path Correction Process)

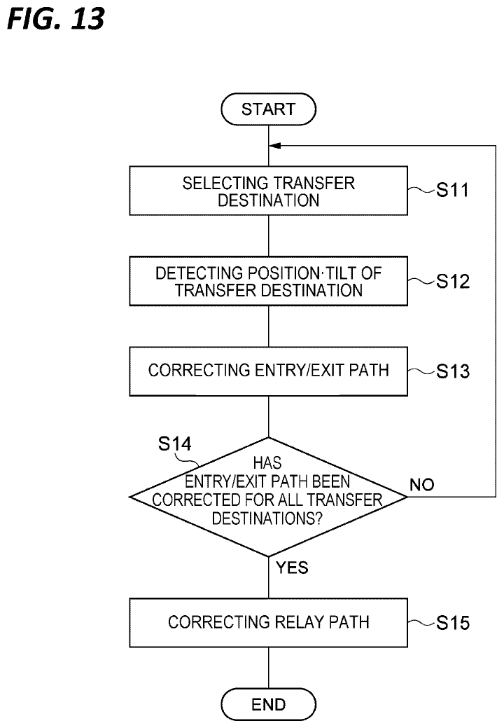

As illustrated in FIG. 13, the controller 100 first performs steps S11, S12, and S13. In step S11, the control unit 111 selects one of transfer destinations TD. In step S12, the detection unit 113 detects the position and the tilt of the selected transfer destination TD by, for example, the object sensor 40. In step S13, the path correction unit 114 corrects the entry/exit path MP2 based on the result of detection of the position and the tilt of the transfer destination TD.

Next, the controller 100 performs steps S14 and S15. In step S14, the path correction unit 114 checks whether the correction of the entry/exit path MP2 has been completed for all the transfer destinations TD. When it is determined in step S14 that there is still a transfer destination TD for which the entry/exit path MP2 has not been corrected, the controller 100 returns the process to step S11. When it is determined in step S14 that the correction of the entry/exit path MP2 has been completed for all the transfer destinations TD, the controller 100 performs step S15. In step S15, the path generation unit 116 generates at least one relay path MP3 that connects the plurality of entry/exit paths MP2 to each other. Then, the path generation process is completed.

### (Control Process)

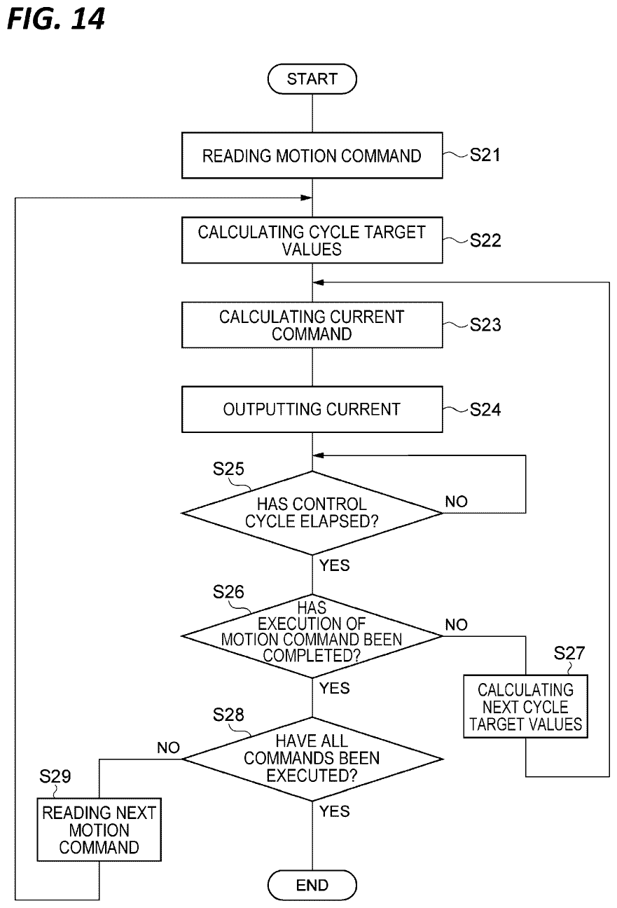

As illustrated in FIG. 14, the controller 100 first performs steps S21 and S22. In step S21, the control unit 111 reads a first motion command among the plurality of motion commands described above. In step S22, the control unit 111 generates the target position and the target posture of the hand 33 in a first control cycle (hereinafter, referred to as “cycle target values”).

Next, the controller 100 performs steps S23 and S24. In step S23, the control unit 111 generates a current command for the motors M1, M2, and M3, and the motors M11 and M12 based on the cycle target values. In step S24, the control unit 111 outputs the current corresponding to the current command to the motors M1, M2, M3, M11, and M12.

Next, the controller 100 performs steps S25 and S26. In step S25, the controller 100 waits for the elapse of the control cycle. In step S26, the control unit 111 checks whether the execution of the motion command has been completed (whether the hand 33 has reached the target position and the target posture of the motion command). When it is determined in step S26 that the execution of the motion command has not been completed, the controller 100 executes step S27. In step S27, the control unit 111 calculates the next cycle target values. Then, the controller 100 returns the process to step S23.

When it is determined in step S26 that the execution of the motion command has been completed, the controller 100 performs step S28. In step S28, the control unit 111 checks whether the execution of all the motion commands has been completed. When it is determined in step S28 that there is still a motion command that has not been executed, the controller 100 performs step S29. In step S29, the control unit 111 reads the next motion command. Then, the controller 100 returns the process to step S22. When it is determined in step S28 that the execution of all the motion commands has been completed, the controller 100 completes the control process.

### SUMMARY

The present disclosure includes the following configuration.

(1) A substrate transfer robot system 6 including: a first arm unit 20 that includes a first set of arms 22 and 23 connected to each other to rotate around horizontal axes Ax1, Ax2, and Ax3, respectively, and that changes a position of an end 24 with respect to a base in a first plane PL1; a second arm unit 30 that includes a second set of arms 31 and 32 connected in an order from the end 24 to rotate around axes Ax11 and Ax12, respectively, perpendicular to the horizontal axes Ax1, Ax2, and Ax3, and a hand 33 supporting a substrate W in an arm of the second set of arms 31 and 32, which is farthest from the end 24, and that changes a position of the hand 33 with respect to the end 24 in a second plane PL2 perpendicular to the first plane PL1; and a controller 111 that controls the first arm unit 20 and the second arm unit 30 to move the hand 33 while compensating, by the first arm unit 20, for a displacement of the hand 33 caused by a change in amount of deflection of the first arm unit 20 and the second arm unit 30.

By operating the first arm unit 20 and the second arm unit 30 in combination, the substrate W may be transferred across a wide area. Meanwhile, when the first arm unit 20 and the second arm unit 30 operate in combination, the displacement of the substrate W caused by the change in amount of deflection of the first arm unit 20 and the second arm unit 30 increases. The controller 111 controls the first arm unit 20 to compensate for the displacement of the hand 33 caused by the change in deflection amount. Therefore, it is possible to achieve both the transfer of the substrate W across the wide area and the accuracy of transfer of the substrate W.

(2) The substrate transfer robot system 6 described in (1), wherein the first arm unit 20 includes an end joint J3 that rotates the end 24 around the horizontal axis Ax3, one or more arm joints J1 and J2 that change a position of the end joint J3 with respect to the base in the first plane PL1, the displacement of the hand 33 caused by the change in amount of deflection includes a change in tilt and height of the hand 33, and the controller 111 controls the end joint J3 to compensate for the tilt of the hand 33 caused by the change in amount of deflection, and controls the one or more arm joints J1 and J2 to compensate for the change in height of the hand 33 caused by the change in amount of deflection.

The change in both tilt and height of the hand 33 caused by the change in deflection amount may easily be compensated for by the first arm unit 20.

(3) The substrate transfer robot system 6 described in (1) or (2), wherein the controller 111 controls the first arm unit 20 to compensate for the change in tilt and height of the hand 33 caused by the change in amount of deflection, while moving the hand 33 in a horizontal direction.

The accuracy of transfer of the substrate W may be further improved.

(4) The substrate transfer robot system 6 described in (3), wherein the controller 111 controls the first arm unit 20 and the second arm unit 30 to transfer the substrate W to a plurality of transfer destinations TD, and controls the first arm unit 20 to compensate for the displacement of the hand 33 caused by the change in amount of deflection with a specific compensation amount for each of the plurality of transfer destinations TD.

The accuracy of transfer of the substrate W may be improved at each of the plurality of transfer destinations TD.

(5) The substrate transfer robot system 6 described in (3), wherein the controller 111 controls the first arm unit 20 and the second arm unit 30 based on a pre-generated motion path to compensate, by the first arm unit 20, for the displacement of the hand 33 caused by the change in amount of deflection.

The displacement of the hand 33 caused by the change in amount of deflection may easily be compensated for with a high reproducibility.

(6) The substrate transfer robot system 6 described in (5), wherein the motion path includes a path that changes the tilt and the height of the hand 33 in an opposite direction to the change in tilt and height of the hand 33 caused by the change in amount of deflection, which the hand 33 is moving in the horizontal direction.

The accuracy of transfer of the substrate W may be further improved.

The substrate transfer robot system 6 described in (6), wherein the controller 111 combines the change in tilt and height of the hand 33 caused by the change in amount of deflection and the change in tilt and height of the hand 33 caused by the path, and controls the first arm unit 20 and the second arm unit 30 such that the tilt and the height of the hand 33 are within a specific range with respect to a horizontal line, while the hand 33 is moving in the horizontal direction.

The accuracy of transfer of the substrate W may be further improved.

(8) The substrate transfer robot system 6 described in (7), wherein the path is a path that moves the hand 33 along the horizontal line between a transfer destination TD of the substrate W and a predetermined position away from the transfer destination TD. The accuracy of transfer of the substrate W may be further improved.

(9) The substrate transfer robot system 6 described in (7), wherein the path is a path that descends the hand 33 to prevent or suppress the hand 33 from ascending due to the change in amount of deflection while the hand 33 is moving in a direction approaching the base along the horizontal line.

The accuracy of transfer of the substrate W may be further improved.

(10) The substrate transfer robot system 6 described in (5), further including: a detection unit 113 that detects a position and a tilt of a transfer destination TD of the substrate W in an actual environment; and a path correction unit 114 configured to correct the motion path based on a result of detection of the position and the tilt of the transfer destination TD.

The compensation for the displacement of the substrate W caused by the change in deflection amount may easily be applied to the actual environment.

(11) The substrate transfer robot system 6 described in (10), wherein the motion path includes a plurality of entry/exit paths, for a plurality of transfer destinations TD, to each move the hand 33 into/out of a corresponding transfer destination along the horizontal direction while compensating for the change in tilt and height of the hand 33 caused by the change in amount of deflection, and a relay path that connects the plurality of entry/exit paths to each other, and the detection unit 113 detects a position and a tilt of each of the plurality of transfer destinations TD, and the path correction unit 114 corrects a corresponding entry/exit path based on a result of detection of the position and the tilt of each of the plurality of transfer destinations TD, and corrects the relay path based on the plurality of corrected entry/exit paths.

The compensation for the displacement of the substrate W caused by the change in deflection amount may easily be applied to the actual environment.

(12) The substrate transfer robot system 6 described in (10), wherein the detection unit 113 detects a height and a thickness of the substrate W placed in the transfer destination TD, and based on a result of detection of the height and the thickness of the substrate W, detects the position and the tilt of the transfer destination TD.

The information on the height and the thickness of the substrate W may be used to detect the position and the tilt of the transfer destination TD.

(13) The substrate transfer robot system 6 described in (12), further including: an object sensor provided in the hand 33, wherein the detection unit 113 detects the height and the thickness of the substrate W based on a position of the hand 33 when the object sensor detects the substrate W placed in the transfer destination TD.

The object sensor provided in the hand 33 may be used to detect the position and the tilt of the transfer destination TD.

(14) The substrate transfer robot system 6 described in (13), wherein the detection unit 113 repeatedly detects the height and the thickness of the substrate W while changing the tilt of the hand 33, and detects the tilt of the transfer destination TD based on a tilt of the hand 33 when the thickness of the substrate W becomes smallest.

Even when the thickness of the substrate W is unknown, the object sensor provided in the hand 33 may be used to detect the tilt of the transfer destination TD.

(15) The substrate transfer robot system 6 described in (13), wherein based on a rotation angle of each of the first set of arms 22 and 23 and the second set of arms 31 and 32 when the object sensor detects the substrate W displaced in the transfer destination TD, and the amount of deflection, the detection unit 113 calculates the position of the hand 33 when the object sensor detects the substrate W, and based on the calculated position of the hand 33, the detection unit 113 detects the height and the thickness of the substrate W.

The precision of detection of the position and the tilt of the transfer destination TD by the object sensor provided in the hand 33 may be improved.

(16) The substrate transfer robot system 6 described in (5), further including: an acquisition unit 115 that acquires a result of actual measurement of the displacement of the hand 33 caused by the change in amount of deflection; and a path generation unit 116 that generates the motion path based on the result of actual measurement to compensate for the displacement of the substrate caused by the change in amount of deflection.

The efficiency of generating the motion path to compensate for the displacement of the substrate W may be improved.

(17) The substrate transfer robot system 6 described in (16), wherein the acquisition unit 115 acquires the result of actual measurement of the displacement of the hand 33 caused by the change in amount of deflection, at each of a plurality of transfer destinations TD, the path generation unit 116 generates an entry/exit path for each of the plurality of transfer destinations TD based on the result of actual measurement to move the hand 33 into/out of a corresponding transfer destination along a horizontal line while compensating for the displacement of the substrate W caused by the change in amount of deflection, generates a relay path that connects a plurality of entry/exit paths generated for the plurality of transfer destinations, respectively, to each other, and generates the motion path including the plurality of entry/exit paths and the relay path.

It is possible to easily generate the motion path to compensate for the displacement of the substrate W caused by the change in amount of deflection with a unique compensation amount, for each of the plurality of transfer destinations TD.

(18) A semiconductor transfer apparatus 2 including: a housing 4 that accommodates the substrate transfer robot system 6 described in (1); a cassette support 3 that is provided in the housing 4, and supports a cassette 9 accommodating a substrate W; and a pre-aligner 5 that is provided in the housing 4, and rotates the substrate W, wherein the controller 111 controls the first arm unit 20 and the second arm unit 30 to move the hand 33 into/out of each of a plurality of transfer destinations including the pre-aligner 5 and the cassette 9, while compensating, by the first arm unit 20, for the displacement of the hand 33 caused by the change in amount of deflection.

(19) A semiconductor manufacturing apparatus 1 including: the semiconductor transfer apparatus 2 described in (15); and a processing apparatus 7 that is connected to the semiconductor transfer apparatus 2, and performs a processing for forming a semiconductor on the substrate W.

(20) A control method including: in order to transfer a substrate W to a transfer destination TD, controlling a first arm unit 20 that includes a first set of arms 22 and 23 connected to each other to rotate around horizontal axes Ax1, Ax2, and Ax3, respectively, and that changes a position of an end 24 with respect to a base in a first plane PL1, and a second arm unit 30 that includes a second set of arms 31 and 32 connected in an order from the end 24 to rotate around axes Ax11 and Ax12, respectively, perpendicular to the horizontal axes Ax1, Ax2, and Ax3, and a hand 33 supporting the substrate W in an arm of the second set of arms 31 and 32, which is farthest from the end 24, and that changes a position of the hand 33 with respect to the end 24 in a second plane PL2 perpendicular to the first plane PL1; and during a transfer of the substrate W, controlling the first arm unit 20 and the second arm unit 30 to move the hand 33 while compensating, by the first arm unit 20, for a displacement of the substrate W caused by a change in amount of deflection of the first arm unit 20 and the second arm unit 30.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate transfer robot system comprising:
a first arm module including a first set of arms connected to each other to individually rotate around a horizontal axis, and configured to change a position of an end with respect to a base in a first plane;
a second arm module including a second set of arms connected in an order from the end to individually rotate around an axis perpendicular to the horizontal axis, and a hand supporting a substrate in an arm of the second set of arms, which is farthest from the end, and configured to change a position of the hand with respect to the end in a second plane perpendicular to the first plane; and
a controller configured to control the first arm module and the second arm module to move the hand while compensating, by the first arm module, for a displacement of the hand caused by a change in amount of deflection of the first arm module and the second arm module.

2. The substrate transfer robot system according to claim 1, wherein the first arm module includes
an end joint that rotates the end around the horizontal axis,
at least one arm joint that changes a position of the end joint with respect to the base in the first plane,
the displacement of the hand caused by the change in amount of deflection includes a change in tilt and height of the hand, and
the controller
controls the end joint to compensate for the tilt of the hand caused by the change in amount of deflection, and
controls the at least one arm joint to compensate for the change in height of the hand caused by the change in amount of deflection.

3. The substrate transfer robot system according to claim 1, wherein the controller controls the first arm module to compensate for the change in tilt and height of the hand caused by the change in amount of deflection, while moving the hand in a horizontal direction.

4. The substrate transfer robot system according to claim 3, wherein the controller controls the first arm module and the second arm module to transfer the substrate to a plurality of transfer destinations, and controls the first arm module to compensate for the displacement of the hand caused by the change in amount of deflection with a specific compensation amount for each of the plurality of transfer destinations.

5. The substrate transfer robot system according to claim 3, wherein the controller controls the first arm module and the second arm module based on a pre-generated motion path to compensate, by the first arm module, for the displacement of the hand caused by the change in amount of deflection.

6. The substrate transfer robot system according to claim 5, wherein the motion path includes a path that changes the tilt and the height of the hand in an opposite direction to the change in tilt and height of the hand caused by the change in amount of deflection, which the hand is moving in the horizontal direction.

7. The substrate transfer robot system according to claim 6, wherein the controller combines the change in tilt and height of the hand caused by the change in amount of deflection and the change in tilt and height of the hand caused by the path, and controls the first arm module and the second arm module such that the tilt and the height of the hand are within a specific range with respect to a horizontal line, while the hand is moving in the horizontal direction.

8. The substrate transfer robot system according to claim 7, wherein the path is a path that moves the hand along the horizontal line between a transfer destination of the substrate and a predetermined position away from the transfer destination.

9. The substrate transfer robot system according to claim 7, wherein the path is a path that descends the hand to prevent the hand from ascending due to the change in amount of deflection while the hand is moving in a direction approaching the base along the horizontal line.

10. The substrate transfer robot system according to claim 5, further comprising:
a detector configured to detect a position and a tilt of a transfer destination of the substrate in an actual environment; and
a path corrector configured to correct the motion path based on a result of detection of the position and the tilt of the transfer destination.

11. The substrate transfer robot system according to claim 10, wherein the motion path includes
a plurality of entry/exit paths, for a plurality of transfer destinations, to each move the hand into/out of a corresponding transfer destination along the horizontal direction while compensating for the change in tilt and height of the hand caused by the change in amount of deflection, and
a relay path that connects the plurality of entry/exit paths to each other, and
the detector detects a position and a tilt of each of the plurality of transfer destinations, and
the path corrector
corrects a corresponding entry/exit path based on a result of detection of the position and the tilt of each of the plurality of transfer destinations, and
corrects the relay path based on the plurality of corrected entry/exit paths.

12. The substrate transfer robot system according to claim 10, wherein the detector
detects a height and a thickness of the substrate placed in the transfer destination, and
based on a result of detection of the height and the thickness of the substrate, detects the position and the tilt of the transfer destination.

13. The substrate transfer robot system according to claim 12, further comprising:
an object sensor provided in the hand,
wherein the detector detects the height and the thickness of the substrate based on a position of the hand when the object sensor detects the substrate placed in the transfer destination.

14. The substrate transfer robot system according to claim 13, wherein the detector
repeatedly detects the height and the thickness of the substrate while changing the tilt of the hand, and
detects the tilt of the transfer destination based on a tilt of the hand when the thickness of the substrate becomes smallest.

15. The substrate transfer robot system according to claim 13, wherein based on a rotation angle of each of the first set of arms and the second set of arms when the object sensor detects the substrate displaced in the transfer destination, and the amount of deflection, the detector calculates the position of the hand when the object sensor detects the substrate, and
based on the calculated position of the hand, the detector detects the height and the thickness of the substrate.

16. The substrate transfer robot system according to claim 5, further comprising:
an acquisition device configured to acquire a result of actual measurement of the displacement of the hand caused by the change in amount of deflection; and
a path generator configured to generate the motion path based on the result of actual measurement to compensate for the displacement of the substrate caused by the change in amount of deflection.

17. The substrate transfer robot system according to claim 16, wherein the acquisition device acquires the result of actual measurement of the displacement of the hand caused by the change in amount of deflection, at each of a plurality of transfer destinations,
the path generator
generates an entry/exit path for each of the plurality of transfer destinations based on the result of actual measurement to move the hand into/out of a corresponding transfer destination along a horizontal line while compensating for the displacement of the substrate caused by the change in amount of deflection,
generates a relay path that connects a plurality of entry/exit paths generated for the plurality of transfer destinations, respectively, to each other, and
generates the motion path including the plurality of entry/exit paths and the relay path.

18. A semiconductor transfer apparatus comprising:
a housing configured to accommodate the substrate transfer robot system according to claim 1;
a cassette support provided in the housing, and configured to support a cassette accommodating a substrate; and
a pre-aligner provided in the housing, and configured to rotate the substrate,
wherein the controller controls the first arm module and the second arm module to move the hand into/out of each of a plurality of transfer destinations including the pre-aligner and the cassette, while compensating, by the first arm module, for the displacement of the hand caused by the change in amount of deflection.

19. A semiconductor manufacturing apparatus comprising:
the semiconductor transfer apparatus according to claim 15; and
a processing apparatus connected to the semiconductor transfer apparatus, and configured to perform a processing for forming a semiconductor on the substrate.

20. A control method comprising:
in order to transfer a substrate to a transfer destination,
controlling
a first arm module including a first set of arms connected to each other to individually rotate around a horizontal axis, and configured to change a position of an end with respect to a base in a first plane, and
a second arm module including a second set of arms connected in an order from the end to individually rotate around an axis perpendicular to the horizontal axis, and a hand supporting the substrate in an arm of the second set of arms, which is farthest from the end, and configured to change a position of the hand with respect to the end in a second plane perpendicular to the first plane; and
during a transfer of the substrate, controlling the first arm module and the second arm module to move the hand while compensating, by the first arm module, for a displacement of the substrate caused by a change in amount of deflection of the first arm module and the second arm module.
